(19) United States
(12) Patent Application Publication
(10) Pub. No.: US 2022/0302660 A1
(43) Pub. Date: Sep. 22, 2022

(54) SEMICONDUCTOR STORAGE DEVICE

(71) Applicant: Kioxia Corporation, Tokyo (JP)

(72) Inventors: Masaaki TAKAHASHI, Yokohama Kanagawa (JP); Shiro HARASHIMA, Sagamihara Kanagawa (JP); Takeshi IKUTA, Yokohama Kanagawa (JP); Akinobu HIROTA, Yokohama Kanagawa (JP)

(73) Assignee: Kioxia Corporation, Tokyo (JP)

(21) Appl. No.: 17/347,886

(22) Filed: Jun. 15, 2021

(30) Foreign Application Priority Data
Mar. 16, 2021 (JP) 2021-042683

(51) Int. Cl. H01R 24/62; H01R 13/66; H01R 13/502; H01R 12/52

(52) U.S. Cl. CPC H01R 24/62; H01R 13/6658; H01R 13/5025; H01R 12/52; G06K 19/07732

(57) ABSTRACT

According to one embodiment, a semiconductor storage device includes: a casing, a first board, a second board, a semiconductor memory component, a connector, and a flexible conductive part. The first board is in the casing. The second board is in the casing. The semiconductor memory component is in the casing. The semiconductor memory component is on the first board. The connector is connectable to a host device. The connector is mounted on the second board, the connector protruding from the casing. The flexible conductive part is between the first board and the second board. The flexible conductive part electrically connects the first board and the second board. The flexible conductive part is bendable.

### CROSS-REFERENCE TO RELATED APPLICATION

This application is based upon and claims the benefit of priority from Japanese Patent Application No. 2021-042683, filed Mar. 16, 2021; the entire contents of which are incorporated herein by reference.

### FIELD

Embodiments described herein relate generally to a semiconductor storage device.

### BACKGROUND

A portable semiconductor storage device that includes a connector protruding from a casing and a storage cell housed in the casing, is connected to a host connector of a host device, and carries out information communication with respect to the host device is known.

### BRIEF DESCRIPTION OF THE DRAWINGS

FIG. 1 is a perspective view showing a semiconductor storage device according to a first embodiment.

FIG. 2 is a perspective view showing boards and electronic components which are housed in the semiconductor storage device shown in FIG. 1.

FIG. 3 is a perspective view showing a state in which the semiconductor storage device shown in FIG. 1 is connected to a host connector of a host device.

FIG. 4 is a cross-sectional view showing a state in which an external force is applied to the semiconductor storage device shown in FIG. 1 is connected to the host connector of the host device on an upper portion of the semiconductor storage device.

FIG. 5 is a cross-sectional view showing a state in which an external force is applied to the semiconductor storage device shown in FIG. 1 is connected to the host connector of the host device on an upper portion of the semiconductor storage device and the board is inclined via a flexible conductive part.

FIG. 6 is a perspective view showing a semiconductor storage device according to a second embodiment.

FIG. 7 is a side view showing a semiconductor storage device according to a third embodiment.

FIG. 8 is a plan view showing an inner structure of the semiconductor storage device according to the third embodiment.

### DETAILED DESCRIPTION

According to one embodiment, a semiconductor storage device includes: a casing, a first board, a second board, a semiconductor memory component, a connector, and a flexible conductive part. The first board is in the casing. The second board is in the casing. The semiconductor memory component is in the casing. The semiconductor memory component is on the first board. The connector is connectable to a host device. The connector is mounted on the second board, the connector protruding from the casing. The flexible conductive part is between the first board and the second board. The flexible conductive part electrically connects the first board and the second board. The flexible conductive part is bendable.

### First Embodiment

Hereinafter, semiconductor storage devices according to the first embodiment will be described with reference to the drawings.

In the following description, the same reference signs are given to components having the same or similar function. Duplicate description of these components may be omitted. In this specification, the term “connect” is not limited to physical connection, and the meaning of the term also includes electrical connection. In this specification, the term “adjacent to each other” is not limited to a case in which two members serving as objects are adjacent to each other, and the meaning of the term also includes a case in which another member exists between the two members serving as objects.

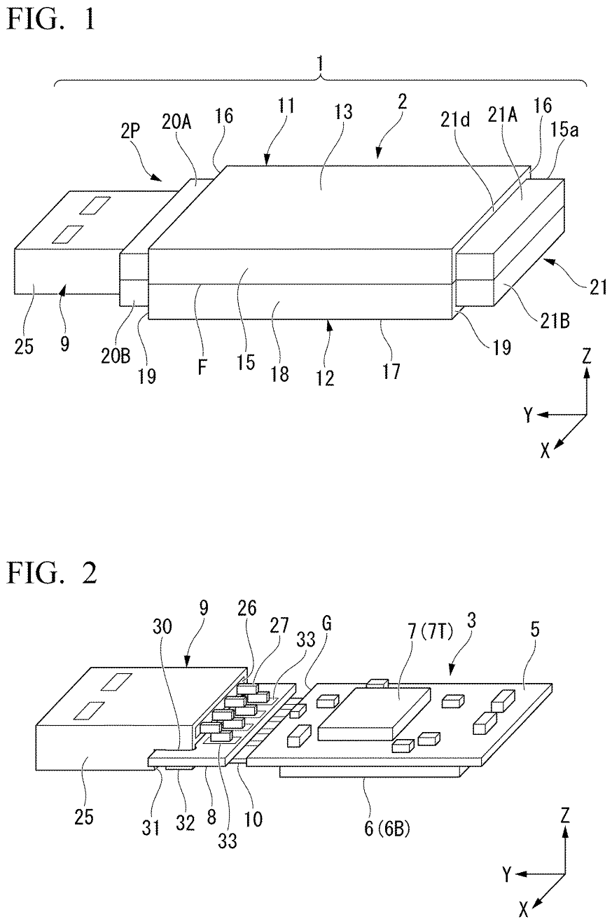

FIG. 1 is a perspective view, for example, showing a semiconductor storage device according to a first embodiment.

FIG. 2 is a perspective view, for example, showing an inner structure of the semiconductor storage device 1 shown in FIG. 1.

The semiconductor storage device 1 may be referred to as, for example, a USB memory, a USB flash drive (UFD), an electronic device, a semiconductor device, a USB device, a storage device, auxiliary storage device, or a removable medium. The semiconductor storage device 1 may be another device.

As shown in FIG. 1, the semiconductor storage device 1 according to the first embodiment is formed in, for example, an elongated plate having a flat rectangular cross-section. The semiconductor storage device 1 may be formed in another shape. As shown in FIGS. 1, 2, or the like, in this specification, the X-axis, the Y-axis, and the Z-axis are defined. The X-axis, the Y-axis, and the Z-axis are orthogonal to each other. The X-axis extends in the width direction of the semiconductor storage device 1. The Y-axis extends in the longitudinal direction of the semiconductor storage device 1. The Z-axis extends in the thickness direction of the semiconductor storage device 1. That is, the Z-axis extends in the thickness direction of each of a first board 5 and a second board 8. In the explanation of this specification, for convenience, the direction along the Z-axis direction may be represented as “vertical”, the direction along the Y-axis direction may be represented as “right and left”.

As shown in FIGS. 1 and 2, a module 3 is housed in a flat and hollow casing 2 (housing) that is elongated in the Y-axis direction in the semiconductor storage device 1.

The module 3 may include, for example, a first board 5, a flash memory 6 (semiconductor memory component), a controller 7 (semiconductor memory component), a second board 8, a connector 9, and a flexible conductive part 10. The flexible conductive part 10 is an example of a connecting substrate. FIG. 1 is a perspective view showing a state in which the semiconductor storage device 1 is horizontally disposed and shows a state in which the semiconductor storage device 1 is disposed such that the connector 9 is directed to the left. FIG. 2 shows a state in which the module 3 removed from the casing 2 is disposed and directed to the same direction as that of FIG. 1.

Note that, the connector 9 is formed in a shape having a flat rectangular cross-section. The connector 9 is connected to a host connector in a state in which, generally, the connector 9 is horizontally disposed so as to extend in the horizontal direction as shown in FIG. 1; however, the direction of the connector 9 depends on the direction of the host connector of the host device which will be described later. Consequently, when the connector 9 is connected to the host device in the state shown in FIG. 1, the semiconductor storage device 1 is in a reference posture.

The casing 2 is an example of a housing formed of a hard resin. The casing 2 includes a first casing member 11 and a second casing member 12. The casing 2 has an opening 2P. The number of the opening 2P may be greater than or equal to two.

The first casing member 11 includes a casing plate 13 that is formed in a rectangular shape having a long side extending in the Y-axis direction, side walls 15 that are formed integrally with the casing plate 13 at the long sides of the casing plate 13, and end walls 16 that are formed at the short sides of the casing plate 13. A thin housing space is formed by the casing plate 13, the side walls 15, and the end walls 16. A portion having a thickness that is approximately half of the thickness of the module 3 is housed in the housing space.

The second casing member 12 includes a casing plate 17 that is formed in a rectangular shape having a long side extending in the Y-axis direction, side walls 18 that are formed integrally with the casing plate 17 at the long sides of the casing plate 17, and end walls 19 that are formed at the short sides of the casing plate 17. A thin housing space is formed by the casing plate 17, the side walls 18, and the end walls 19. A portion having a thickness that is approximately half of the thickness of the module 3 is housed in the housing space.

The first casing member 11 and the second casing member 12 have the same shape as each other. Accordingly, the casing plate 13 is the same as the casing plate 17 in width, length, and thickness. The side wall 15 is the same as the side wall 18 in width, length, and thickness. The end wall 16 is the same as the end wall 19 in width, length, and thickness.

The side wall 15 of the first casing member 11 is butt jointed to the side wall 18 of the second casing member 12. The end wall 16 of the first casing member 11 is butt-jointed to the end wall 19 of the second casing member 12. The butt-jointed portions of the walls are connected to each other by a welding method such as ultrasonic-wave welding method and thereby combined together. Here, the “butt-jointed portion” is the butt-jointed portion at which the two side walls 15 and 18 are butt-jointed to each other, and the butt-jointed portion at which the two end walls 16 and 19 are butt-jointed to each other. The hollow casing 2 is configured by combining the first casing member 11 and the second casing member 12 together. The module 3 is housed in the casing 2. A method of combining the first casing member 11 and the second casing member 12 together is not limited to the welding method. Another joining method such as a bonding method or the like may be used, a connecting method of fitting a recess portion and a projecting portion to each other may be used, or a connecting method of using a connecting part such as a bolt, a screw, or the like may be used.

In the case of connecting the first casing member 11 to the second casing member 12 by welding, a welded portion is provided at the butt-jointed portion between the side walls 15 and 18 and the butt-jointed portion between the end walls 16 and 19. In the case of connecting the first casing member 11 to the second casing member 12 by bonding, a bonding portion is provided at the butt-jointed portion between the side walls 15 and 18 and the butt-jointed portion between the end walls 16 and 19. In the example shown in FIG. 1, the first casing member 11 and the second casing member 12 are combined together by welding. Because of this, the butt-jointed portion between the side walls 15 and 18 and the butt-jointed portion between the end walls 16 and 19 is a welded portion F. In this state, since the first casing member 11 and the second casing member 12 have the same shape as each other, the aforementioned welded portion F is formed on the X-Y plane. In the embodiment, the first board 5 and the second board 8 are surrounded by the first casing member 11 and the second casing member 12. The first casing member 11 is disposed to cover the first board 5 and the second board 8 so as to be directed from the first side to the second side of the thickness direction (Z-axis direction) of each of the first board 5 and the second board 8 (in the direction opposite to the direction represented by the arrow Z shown in FIG. 1). The second casing member 12 is disposed to cover the first board 5 and the second board 8 so as to be directed from the second side to the first side of the thickness direction (Z-axis direction) of each of the first board 5 and the second board 8 (in the direction represented by the arrow Z shown in FIG. 1).

A projecting wall 20 having a square-tube shape is formed at the portion at which the end walls 16 and 19 are joined at one end side (left end side) in the longitudinal direction of the casing 2. An opening 2P that is communicated with the internal space of the casing 2 is formed at the portion at which the end walls 16 and 19 are joined. The projecting wall 20 is formed so as to have the opening 2P. For this reason, the projecting wall 20 is provided so as to cause the internal space of the casing 2 to be communicated with the outside of the casing 2. The connector 9 is provided so as to pass through the opening 2P and the projecting wall 20 and protrude to the outside. The connector 9 protrudes from the casing 2 through the opening 2P.

The projecting wall 20 includes a frame-shaped projecting portion 20A that protrudes from the end wall 16 of the first casing member 11 and a frame-shaped projecting portion 20B that protrudes from the end wall 19 of the second casing member 12. The projecting wall 20 is configured to have a square tube shape by assembling the projecting portion 20A and the projecting portion 20B. Similar to the configuration in which the first casing member 11 and the second casing member 12 are joined to each other by the aforementioned welding, the butt jointed portion between the projecting portion 20A and the projecting portion 20B is welded by welding or the like. The projecting wall 20 having a square-tube shape is formed so as to have a butt-jointed configuration.

A block shaped protruding portion 21 is formed at the portion at which the end walls 16 and 19 are joined at the other end side (right end side) in the longitudinal direction of the casing 2. The block shaped protruding portion 21 has a shape such that the casing 2 is stretched. The protruding portion 21 includes a halved protruding portion 21A that protrudes from the end wall 16 of the first casing member 11 and a halved protruding portion 21B that protrudes from the end wall 19 of the second casing member 12. The halved protruding portion 21A and the halved protruding portion 21B are combined together by connecting the first casing member 11 and the second casing member 12 integrally into one body. The protruding portion 21 is configured by the halved protruding portion 21A and the halved protruding portion 21B which are combined together. At the other end of the casing 2, the protruding portion 21 protrudes from the end walls 16 and 19 so as to cause the casing 2 to extend therefrom via a peripheral step portion 21d.

A cap member (lid, not shown in the drawings) that covers the connector 9 is attached to the protruding portion 21. The protruding portion 21 may be omitted.

A flash memory 6 (storage cell, semiconductor memory component) and a controller 7 (semiconductor memory component) are mounted on the first board 5 housed in the casing 2.

In the configuration shown in FIG. 2, the controller 7 is mounted on an upper surface (first surface) of the first board 5, and the flash memory 6 is mounted on a lower surface (second surface) of the first board 5. The flash memory 6 and the controller 7 may be integrally provided on one of the upper surface and the lower surface of the first board 5 or may be separately mounted on the upper surface and the lower surface of the first board 5.

The first board 5 is, for example, a printed circuit board (PCB). The first board 5 may be other boards such as a flexible printed circuit board (FPC). The first board 5 is formed in a plate form having a rectangular shape (quadrangular shape) in plan view which expands on the X-Y plane. The first board 5 may be formed in another shape.

The flash memory 6 is an example of a first semiconductor memory component and may be referred to as, for example, a non-volatile memory, memory, or a storage circuit (storage). The controller 7 is an example of a second semiconductor memory component and may be referred to as, for example, a control circuit.

The flash memory 6 is an electronic component that stores information (data), for example, a NAND flash memory. Note that, the semiconductor storage device 1 may include a non-volatile memory such as a NOR flash memory, a Magnetoresistive Random Access Memory (MRAM), a Phase change Random Access Memory (PRAM), a Resistive Random Access Memory (ReRAM), a Ferroelectric Random Access Memory (FeRAM), or the like.

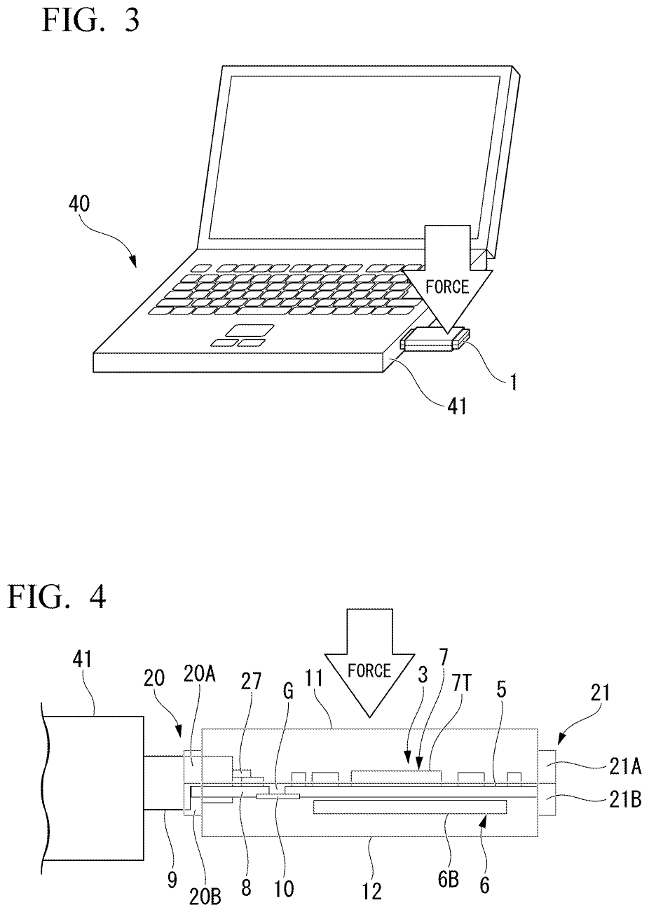

As shown in FIG. 2, the controller 7 is mounted on the upper surface (first surface) of the first board 5. For example, a plurality of terminals provided on the controller 7 are electrically connected to a plurality of circuits or electrodes provided on the upper surface of the first board 5 by solder. The controller 7 may be mounted on the lower surface (second surface) of the first board 5. The controller 7 controls, for example, the semiconductor storage device 1 and controls communication between the semiconductor storage device 1 and a host device 40 shown in FIG. 3 which will be described later.

The connector 9 may be referred to as, for example, a plug, an insertion portion, or a connection portion.

The connector 9 passes through the projecting wall 20 and protrudes from the casing 2 to the outside. The portion of the connector 9 which protrudes to the outside is covered with, for example, the cap member (lid, not shown in the drawings) attachable to the casing 2. The connector 9 is, for example, a male connector (plug) complied with USB Type-C standard. The USB Type-C standard includes, for example, the USB 2.0 Type-C standard, the USB 3.1 Gent Type-C standard, and the USB 3.1 Gen2 Type-C standard. The connector 9 includes a flat-square tube shaped insertion portion 25 formed of a metal, a connection board 26 provided inside the insertion portion 25, and a plurality of (for example, four) connection terminals 27 provided along the connection board 26. In the internal space of the insertion portion 25, the connection board 26 occupies a space having a height substantially half the thickness of the insertion portion 25. The front-ends of the four connection terminals 27 are disposed at the positions at which the front-ends face the internal space of the insertion portion 25 of the connection board 26.

The insertion portion 25 of the connector 9 is inserted into, for example, a USB connector of the host device (female connector, socket). At this time, the connection board 26 and the connection terminals 27 are inserted into a connection port of the host device. Therefore, the connection terminals of the host device are electrically connected to the connection terminals 27 of the semiconductor storage device 1. Consequently, the semiconductor storage device 1 can be electrically connected to the host device.

In the semiconductor storage device 1 according to the embodiment, the second board 8 having a rectangular shape in plan view is disposed between the connector 9 and the first board 5. The second board 8 is a board formed in a rectangular shape (quadrangular shape) in plan view which expands on the X-Y plane. The second board 8 may have a width in the X-axis direction which is the same as that of the first board 5. The second board 8 may have a length that is a fraction of that of the first board 5 in the Y-axis direction. As shown in FIG. 2, the second board 8 is formed in a quadrangular shape in plan view which has a length in the X-axis direction longer than the length in the Y-axis direction. The width of the second board 8 (width in the X-axis direction) is slightly larger than the width of the connector 9 (width in the X-axis direction).

Slit-shaped insertion holes 30 are provided on the second board 8. The slit-shaped insertion holes 30 are formed at the positions at which the connector 9 overlaps the second board 8. The slit-shaped insertion holes 30 are next to the end portion of the second board 8. The slit-shaped insertion holes 30 are provided at the positions close to the end portions in the width direction (the X-axis direction) of the second board 8. A cut-off portion 31 is formed at the lower edge of the insertion portion 25 of the connector 9 in the Z-axis direction. The end portion of the second board 8 is inserted into the cut-off portion 31. Engagement portions 32 that protrude downward (in the Z-axis direction) is formed on part of the insertion portion 25. The engagement portions 32 face the cut-off portion 31.

The cut-off portion 31 is formed on an overall width region from one end to the other end in the X-axis direction of the lower edge of the insertion portion 25. The engagement portions 32 are formed at both ends in the width direction of the insertion portion 25 (both ends in the X-axis direction).

As shown in FIG. 2, the engagement portions 32 are inserted into the insertion holes 30 of the second board 8, and the end portion in the Y-axis direction of the second board 8 is inserted into the cut-off portion 31. With this configuration, the second board 8 is connected to the connector 9. A terminal pad 33 connected to each of the four connection terminals 27 of the connector 9 is provided on the upper surface of the second board 8. Vertical connection conductors such as a via hole or the like which penetrate through the second board 8 in the thickness direction of the second board 8 are provided on the second board 8. The terminal pads 33 are connected to the vertical connection conductors. That is, the terminal pads 33 extend to the lower surface of the second board 8 via the vertical connection conductors.

A gap G is provided between the second board 8 and the first board 5. That is, the first board 5 and the second board 8 are spaced apart from each other. The size of the gap G is slightly larger than the thickness of each of the second board 8 and the first board 5. The flexible conductive part 10 formed of a flexible wiring substrate or the like is disposed under the gap G. That is, the flexible conductive part 10 is between the first board and the second board, electrically connects the first board 5 to the second board 8, and is bendable at the part between the first board 5 and the second board 8. The flexible conductive part 10 is a flexible connecting substrate connecting the first board 5 and the second board 8. The flexible conductive part 10 serving the flexible connecting substrate includes wirings (refer to FIG. 6) extending from the first board 5 to the second board 8. The wirings connect an electrical circuit formed on the first board 5 to an electrical circuit formed on the second board 8. An electrical circuit is formed on the flexible conductive part 10. The electrical circuit is connected to an electrical circuit formed on the lower surface of the second board 8 and an electrical circuit formed on the lower surface of the first board 5 by a connecting method such as a soldering method.

The electrical circuit of the flexible conductive part 10 is electrically connected to the connection terminals 27 of the connector 9 via the four terminal pads 33 of the second board 8.

The electrical circuit of the flexible conductive part 10 extends to the lower surface of the first board 5 and is connected to the electrical circuit formed on the lower surface of the first board 5 via a connecting portion such as solder or the like.

The flexible conductive part 10 functions as a connection conductor that electrically connects the controller 7 or the flash memory 6 which is mounted on the first board 5 to the connection terminals 27 of the connector 9.

The first board 5, the flash memory 6, and the controller 7 form a board-mounted body. The board-mounted body has an upper surface and a lower surface in a thickness direction of the first board 5. In the thickness direction of the board-mounted body (in the thickness direction of the first board 5), the flexible conductive part 10 is disposed at a position lower than or equal to the upper surface and at a position higher than or equal to the lower surface. In other words, in the Z-axis direction shown in

FIGS. 2 and 4, the controller 7 has an upper surface 7T exposed to an upper space of the first board 5, and the flash memory 6 has a lower surface 6B exposed to a lower space of the first board 5. The flexible conductive part 10 is disposed at a position lower than or equal to the upper surface 7T and at a position higher than or equal to the lower surface 6B. Note that, when the controller 7 is not disposed on the first board 5, the surface of the first board 5 on which the controller 7 is disposed as shown in FIG. 4 is the upper surface of the board-mounted body. When the flash memory 6 is not disposed on the first board 5, the surface of the first board 5 on which flash memory 6 is disposed as shown in FIG. 4 is the lower surface of the board-mounted body. When the semiconductor storage device 1 shown in FIG. 1 is used, the semiconductor storage device 1 is connected to the host connector 41 of the host device 40 such as a notebook personal computer or the like shown in FIG. 3. FIG. 3 shows a state of the semiconductor storage device I being connected to the host connector 41 of the host device 40. FIG. 4 shows a state in which a downward external force is applied to the semiconductor storage device 1 shown in FIG. 3.

As shown in FIGS. 3 and 4, of the host device 40 disposed on a horizontal plane of a desk or the like, an insertion hole of the host connector 41 is disposed in horizontal. Accordingly, the semiconductor storage device 1 is connected to the insertion hole of the host connector 41 such that the connector 9 is directed to the left, the semiconductor storage device 1 is in the reference posture such as being disposed in a substantially horizontal direction.

During use of the host device 40 while being connected to the semiconductor storage device 1, it is conceivable that a downward external force represented by the arrow shown in FIGS. 3 and 4 is unexpectedly applied to the semiconductor storage device 1.

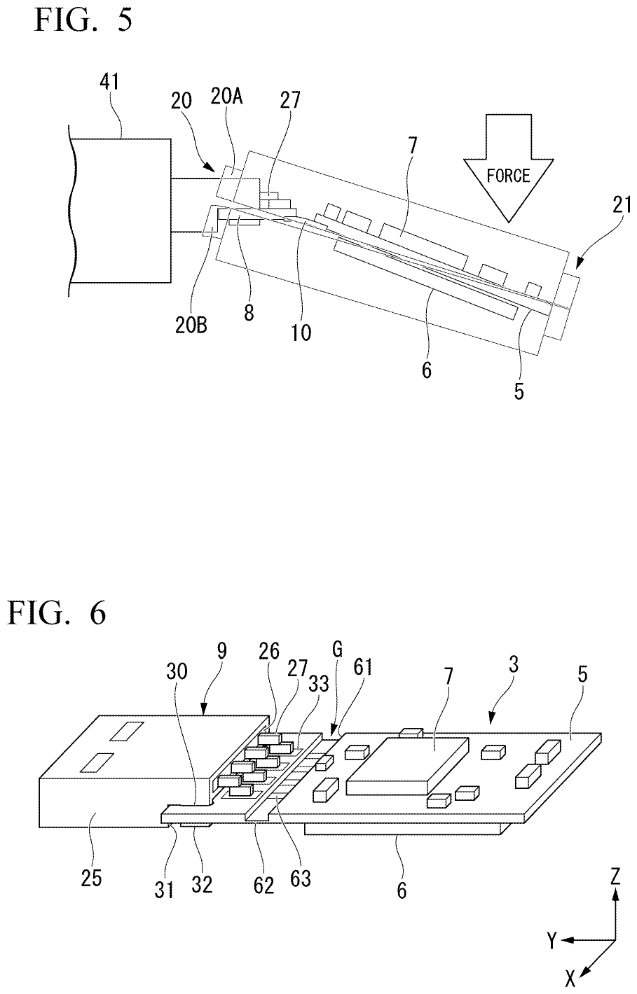

At this time, when the amount of the external force applied to the semiconductor storage device 1 is large, as shown in FIG. 5, the semiconductor storage device 1 is deformed such that the semiconductor storage device 1 is bent downward. The insertion portion 25 of the connector 9 inserted into the host connector 41 is formed of a metal and has a high degree of strength. Because of this, a bending moment force is applied to the connecting portion between the casing 2 formed of resin and the connector 9.

The casing 2 has a configuration in which the first casing member 11 and the second casing member 12 which are formed of resin are welded to each other. That is, the casing 2 includes the welded portion F between the first casing member 11 and the second casing member 12. Therefore, the above-mentioned bending moment force acts on the first casing member 11 and the second casing member 12 to be peeled off each other at the welded portion F. When the above-described bending moment force is smaller than the peel strength of the welded portion F between the first casing member 11 and the second casing member 12, the semiconductor storage device 1 can withstand the aforementioned external force. When the above-described bending moment force is greater than the peel strength of the welded portion F between the first casing member 11 and the second casing member 12, the first casing member 11 and the second casing member 12 are peeled off each other at the welded portion F located close to the connector 9. When the first casing member 11 and the second casing member 12 are peeled off each other at the welded portion F, the aforementioned external force causes the first casing member 11 and the second casing member 12 to be deformed such that the right end side thereof is directed downward as shown in HG. 5.

Due to the deformation, the projecting portion 20A and the projecting portion 20B which are located close to the connector 9 are separated from each other, the first casing member 11 and the second casing member 12 are separated from each other at the welded portion F located around the connector 9 of the casing 2. The portion around the connector 9 of the second casing member 12 is mainly deformed, and therefore the casing 2 is inclined with respect to the extending direction of the connector 9.

In this case, since the first board 5 is connected to the second board 8 via the flexible conductive part 10, the posture of the second board 8 is not changed. However, as shown in FIG. 5, the first board 5 is inclined such that the right end side of the first board 5 is directed downward. That is, by providing the flexible conductive part 10 between the second board 8 and the first board 5, the external force is inhibited from begin applied to the first board 5, it is possible to prevent the first board 5 from being damaged. Additionally, the first casing member 11 and the second casing member 12 are partially peeled off each other at the welded portion F of the casing 2. However, when the external force is removed, due to a restorative force generated at the remaining welded portion F at which the first casing member 11 and the second casing member 12 are not peeled off, the casing 2 restores to an original state before being deformed. Accordingly, it is possible to return to the original configuration in which the first board 5 and the second board 8 are covered with the casing 2 configured of the first casing member 11 and the second casing member 12.

As described above, according to the semiconductor storage device 1 having the configuration shown in FIGS. 1 and 2, in a state in which the semiconductor storage device 1 is connected to the host device 40, even where a large external force is applied to the semiconductor storage device 1 in the downward direction by any possibility, it is possible to prevent the first board 5 disposed inside the casing 2 from being damaged or broken due to bending, only by causing the first casing member 11 and the second casing member 12 to be partially peeled off each other at the welded portion F of the casing 2.

In a state in which this kind of semiconductor storage device is connected to the host connector of the host device, the casing is in a state of protruding to the outside of the host device. For this reason, when the external force is unexpectedly applied to the casing, the external force is applied to the casing or the connection portion between the connector and the casing. When the external force is great, the board disposed inside the casing may be damaged.

This means that the semiconductor storage device is broken, and therefore information cannot be read out from the flash memory.

In contrast, according to the semiconductor storage device 1 having the configuration shown in FIGS. 1 and 2, although the damage occurs such that the first casing member 11 and the second casing member 12 are partially peeled off each other at the welded portion of the casing 2, information can be continuously read out from the flash memory 6, and information can be written in the flash memory 6.

Note that, when the strength of the welded portion or the strength of bonding portion between the first casing member 11 and the second casing member 12 is made greater than required, there is a concern that the first casing member 11 or the second casing member 12 is directly broken due to bending when the aforementioned external force is applied thereto. Accordingly, it is preferable that the strength of the welded portion or the strength of bonding portion between the first casing member 11 and the second casing member 12 be smaller than the bending strength of the first casing member 11 or the second casing member 12.

That is, the semiconductor storage device 1 is configured such that, when the external force is applied to the semiconductor storage device 1, the first casing member 11 and the second casing member 12 are peeled off each other at the welded portion F or the bonding portion as shown in FIG. 5 before the first casing member 11 or the second casing member 12 is broken due to bending. With this configuration, when the external force is applied to the semiconductor storage device 1, the semiconductor storage device 1 according to the embodiment is reliably deformed as shown in FIG. 5, and it is possible to prevent the first board 5 from being broken due to bending.

### Second Embodiment

FIG. 6 is a perspective view showing an inner structure of a semiconductor storage device according to a second embodiment. In the semiconductor storage device according to the second embodiment, identical reference numerals are used for the constituent elements which are identical to those of the semiconductor storage device 1 according to the first embodiment shown in FIG. 2, the explanations of the same constituent elements are omitted or simplified here. In the semiconductor storage device according to the second embodiment, the first board 5 is separated from the second board 8 via a cut-off portion 61. The gap G is formed between the first board 5 and the second board 8 at the portion at which the cut-off portion 61 is formed. A board connection part 62 is provided at a bottom portion of the first board 5 (a first bottom portion, a lower side in the thickness direction of the first board 5) and a bottom portion of the second board 8 (second bottom portion, a lower side in the thickness direction of the second board 8). The bottom portion of the first board 5 and the bottom portion of the second board 8 are integrally connected to each other via the board connection part 62. The board connection part 62 is an example of flexible conductive part. The first board 5 and the second board 8 are formed of a single board (one board). In this configuration, the board connection part 62 is a portion of the single board, and the board connection part 62 is smaller in thickness than that of each of the first board 5 and the second board 8 in the Z-axis direction.

The first board 5, the second board 8, and the board connection part 62 are formed of the same board material.

Before forming the cut-off portion 61, the first board 5 and the second board 8 are formed by one board that is formed of the same board material having the same thickness. The first board 5 and the second board 8 are separated from each other by forming the cut-off portion 61 at a boundary portion between the first board 5 and the second board 8 using groove working.

The board connection part 62 has a thickness of, for example, approximately 0.2 to 0.3 mm. The board connection part 62 has flexibility such that, for example, the board connection part can be bent several times. Furthermore, wirings 63 that connect an electrical circuit formed on the first board 5 to an electrical circuit formed on the second board 8 are incorporated into the board connection part 62. Therefore, the board connection part 62 has the flexibility similar to the flexible conductive part 10 according to the first embodiment. The board connection part 62 functions as the flexible conductive part.

According to the semiconductor storage device having the internal configuration shown in FIG. 6, it is possible to obtain the action and effect which are the same as or similar to those of the semiconductor storage device 1 according to the first embodiment. That is, in a state in which the host connector 41 of the host device 40 is connected to the semiconductor storage device, when a large external force is applied to the semiconductor storage device in the downward direction, the first casing member 11 and the second casing member 12 are partially peeled off each other at the welded portion F of the casing 2, the casing 2 is partially deformed, and the board connection part 62 is curved. As a result, the first board 5 inside the casing 2 is inclined with respect to the extending direction of the connector 9, and it is possible to prevent the first board 5 from being damaged.

Particularly, the board connection part 62 has flexibility such that, for example, the board connection part can be bent several times. However, when the board connection part 62 is repetitively bent, there is a concern that the board connection part 62 is will be damaged. Therefore, in a state in which the semiconductor storage device is connected to the host device 40, when a large external force is once applied to the semiconductor storage device in the downward direction, it is preferable to read out information from the flash memory 6 as soon as possible. Subsequently, it is preferable to copy the read-out information to a storage device such as a SSD (Solid State Drive), a HDD (hard Disk Drive), or the like in the host device 40.

### Third Embodiment

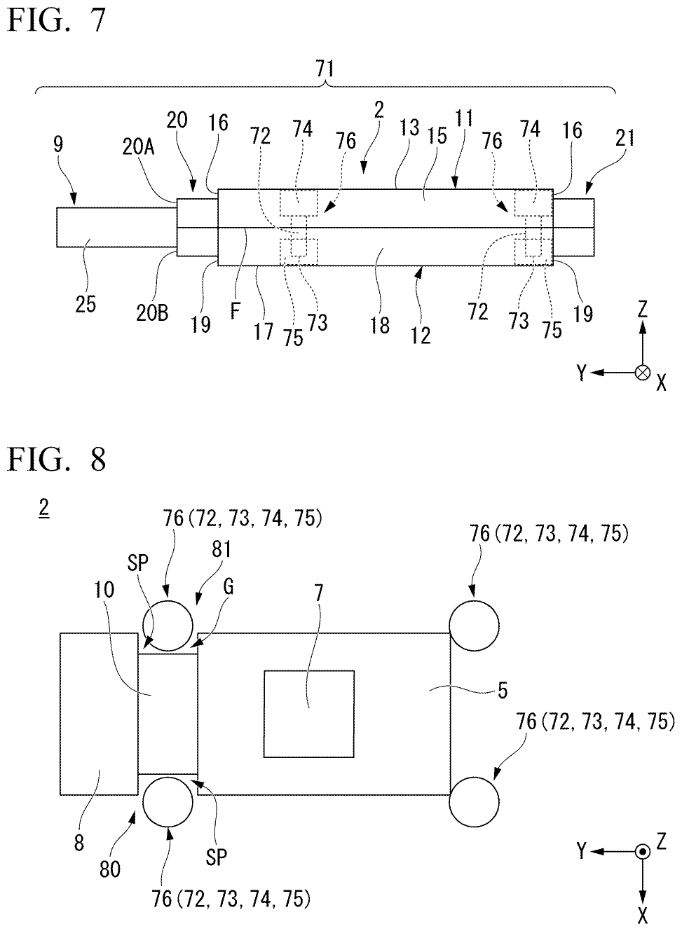

FIG. 7 is a side view showing a semiconductor storage device according to a third embodiment. FM. 8 is a plan view showing an inner structure of the semiconductor storage device according to the third embodiment. In FIG. 8, the shape of the casing 2 is omitted. FIG. 8 shows a positional relationship of the first board 5, the second board 8, the flexible conductive part 10, and engaged portions 76 which are disposed inside the casing 2. As described below, each of the engaged portions 76 is configured by fitting a projected portion 72 into a recess 73.

In the semiconductor storage device according to the third embodiment, identical reference numerals are used for the constituent elements which are identical to those of the semiconductor storage device 1 according to the first embodiment shown in FIG. 2, the explanations of the same constituent elements are omitted or simplified here. In the semiconductor storage device 71 according to the third embodiment, the configuration of the module 3 housed in the casing 2 is similar to the semiconductor storage device 1 according to the first embodiment. That is, the module 3 may include, for example, the first board 5, the flash memory 6, the controller 7, the second board 8, the connector 9, and the flexible conductive part 10. The configuration of the module 3 is similar to that of the semiconductor storage device 1 according to the first embodiment.

The semiconductor storage device according to the third embodiment is different from the configuration according to first embodiment in configuration of the casing 2. The basic structure of the casing 2 of the semiconductor storage device according to the third embodiment is the same as that of the first embodiment. The semiconductor storage device according to the third embodiment is the same as that of the first embodiment in configuration in which the first casing member 11 and the second casing member 12 have the side walls 15 and 18, the end walls 16 and 19, respectively, and in which the casing 2 has the projecting wall 20 and the protruding portion 21. The semiconductor storage device according to the third embodiment is the same as that of the first embodiment in configuration in which the first casing member 11 and the second casing member 12 are connected to each other by a connecting method such as a welding method, a bonding method, or the like which are described above.

The semiconductor storage device according to the third embodiment is different from the first embodiment in configuration in which projected portions 72 directed downward are formed at four positions at the internal side of the first casing member 11 and recesses 73 directed upward are formed at four positions at the internal side of the second casing member 12.

In the third embodiment, not only the first casing member 11 and the second casing member 12 are welded or bonded to each other but also the first casing member 11 and the second casing member 12 are connected to each other by fitting the projected portions 72 into the recesses 73.

The projected portions 72 are each a portion that protrudes downward from a thick portion 74 formed on the lower surface of the casing plate 13 of the first casing member 11. In other words, each of the thick portions 74 is formed between the casing plate 13 and the projected portion 72 and functions as a base at which the projected portion 72 is formed on the casing plate 13.

The recesses 73 are each a portion that is formed on the upper surface of a thick portion 75 formed on the upper surface of the casing plate 17 of the second casing member 12. In other words, each of the thick portions 75 is formed between the casing plate 17 and the recess 73 and functions as a base at which the recess 73 is formed on the casing plate 17.

The projected portion 72 and the recess 73 which face each other are fitted to each other.

In the casing 2, the projected portion 72 that is provided at the position closer to the protruding portion 21 than the connector 9 is formed inside a corner at which the end wall 16 and the side wall 15 intersect with each other. the recess 73 that is provided at the position closer to the protruding portion 21 than the connector 9 is formed inside a corner at which the end wall 19 and the side wall 18 intersect with each other.

As shown in FIG. 8, in the casing 2, the projected portion 72 and the recess 73 that are provided at the positions closer to the connector 9 than the protruding portion 21 are formed at the boundary 80 between the first board 5 and the second board 8. The projected portion 72 and the recess 73 face the gap G. The projected portion 72 and the recess 73 are disposed at both sides of the flexible conductive part 10 in the X-axis direction and is formed so as to sandwich the flexible conductive part 10. The gap G and the flexible conductive part 10 are provided at the boundary portion between the first board 5 and the second board 8. For example, in the X-axis direction, the flexible conductive part 10 is formed such that the width of the flexible conductive part 10 is slightly smaller than the width of the first board 5. Accordingly, as the width of the flexible conductive part 10 becomes narrower, gaps SP are formed at both sides of the flexible conductive part 10 in the X-axis direction. That is, regions 81 that are formed by the gaps SP provided at both sides of the flexible conductive part 10 in the X-axis direction and the gap G in the Y-axis direction is obtained. The thick portions 74 and 75 are located at the regions 81. Therefore, it is easy to ensure the region 81 at which the thick portion 74 is disposed on the casing plate 13, and it is easy to ensure the region 81 at which the thick portion 75 is disposed on the casing plate 17.

In addition to the configuration in which the first casing member 11 and the second casing member 12 are welded or bonded to each other, the casing 2 according to the third embodiment has a configuration in which the first casing member 11 and the second casing member 12 are connected to each other by fitting the projected portion 72 into the recess 73 and thereby forming an engaged portion 76.

When the semiconductor storage device 71 including the casing 2 according to the third embodiment is connected to the host connector 41 of the host device 40 as shown in FIG. 3, when a downward external force is applied to the semiconductor storage device 71, the first casing member 11 and the second casing member 12 are partially peeled off each other at the welded portion F located close to the connector 9 in a way similar to the case shown in FIG. 5. In this case, the first casing member 11 and the second casing member 12 are deformed and the first board 5 can be inclined downward due to the action of the flexible conductive part 10. According to the semiconductor storage device 71 having the configuration shown in FIG. 7, it is possible to obtain the action and effect which are the same as or similar to those of the semiconductor storage device 1 according to the first embodiment.

In a way similar to the case shown in FIG. 5, when the external force is applied to the semiconductor storage device 71, according to deformation of the first casing member 11 and the second casing member 12, the projected portion 72 located close to the connector 9 is removed from the recess 73 or the projected portion 72 is partially extracted from the recess 73. Consequently, the fitting force between the projected portion 72 and the recess 73 becomes weakened.

Here, when the external force applied from the outside of the semiconductor storage device 71 is removed, the posture of the semiconductor storage device 71 with respect to the host connector 41 is returned to be in horizontal. In this case, a user who uses the semiconductor storage device 71 removes the semiconductor storage device 71 from the host connector 41 and causes the projected portion 72 that is extracted from the recess 73 located close to the connector 9 to be fitted into the recess 73 again. Furthermore, the user causes the projected portion 72 being about to be extracted from the recess 73 located close to the connector 9 to be fitted into the recess 73 again.

In this manner, the fitting state of the first casing member 11 and the second casing member 12 is restored and it is possible to restore the casing 2 to be a substantially original state.

According to the embodiment, the casing 2 is obtained which has the configuration in which the recess 73 and the projected portion 72 are fitted to each other and therefore the first casing member 11 and the second casing member 12 are combined together in addition to the configuration in which the first casing member 11 and the second casing member 12 are welded or bonded to each other. The semiconductor storage device 71 includes the casing 2 having the above-described configuration.

In the semiconductor storage device 71 having this configuration, when the external force is applied to the semiconductor storage device 71 from the outside, even where the first casing member 11 and the second casing member 12 are partially peeled off each other at the connecting portion thereof, the effect of reliably restoring the shape of the casing 2 to be the original shape is obtained by fitting the projected portion 72 into the recess 73 again.

Note that, the position at which the projected portion 72 and the recess 73 are disposed between the first casing member 11 and the second casing member 12 is not limited to the example shown in FIG. 7.

In the example shown in FIG. 7, the projected portion 72 is provided on the first casing member 11 of the casing 2, and the recess 73 is provided on the second casing member 12. A configuration in which the recess 73 is provided on the first casing member 11 and the projected portion 72 is provided on the second casing member 12 may be adopted.

In the case of providing a plurality of the projected portions 72 and a plurality of the recesses 73 in the casing 2, of the projected portions 72, some of the projected portions 72 may be provided on the first casing member 11, and the remaining projected portions 72 may be provided on the second casing member 12. The recess 73 that faces the projected portion 72 provided on the first casing member 11 may be provided on the second casing member 12. The projected portion 72 that faces the recess 73 provided on the first casing member 11 may be provided on the second casing member 12.

The number of the projected portions 72 and the number of the recesses 73 which are provided on the first casing member 11 and the second casing member 12 are not limited. The number of the projected portions 72 and the number of the recesses 73 can be selected as necessary. As long as the projected portions 72 and the recesses 73 are provided inside the casing 2, the positions at which the projected portion 72 and the recess 73 are disposed are not limited to the above-described embodiment.

Note that, in the aforementioned embodiment, the case was described in which a flexible substrate or a commonly-used substrate material is used as the flexible conductive part. As the flexible conductive part, a plurality of flexible electroconductive cables, each of which is coated with an insulator, may be used. With the configuration in which the first board 5 and the second board 8 are electrically connected to each other via the electroconductive cables and a gap is provided between the first board 5 and the second board 8, it is possible to obtain the action and effect which are the same as or similar to those of the foregoing embodiments.

As described above, a plurality of embodiments and modified examples were described, the embodiments are not limited to the aforementioned examples. For example, the aforementioned two or more embodiments and modified examples may be combined together, and thereby a combination thereof may be realized.

Moreover, in the foregoing embodiments, when the first casing member 11 and the second casing member 12 are connected to each other, the first casing member 11 and the second casing member 12 may be connected to each other only by fitting using the recesses and the projected portions which are described above without welding or bonding the first casing member 11 and the second casing member 12 to each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a casing having;
a first board in the casing;
a second board in the casing;
a semiconductor memory component in the casing, the semiconductor memory component being on the first board;
a connector connectable to a host device, the connector being mounted on the second board, the connector protruding from the casing;
a flexible conductive part between the first board and the second board, the flexible conductive part electrically connecting the first board and the second board, and the flexible conductive part being bendable.

2. The semiconductor storage device according to claim 1, wherein the first board and the second board are spaced apart from each other, and the flexible conductive part is bendable between the first board and the second board.

3. The semiconductor storage device according to claim 1, wherein
the first board and the second board are formed of one board,
the flexible conductive part is a portion of the board, and
the flexible conductive part is smaller in thickness than that of each of the first board and the second board.

4. The semiconductor storage device according to claim 1, wherein
the flexible conductive part is a flexible connecting substrate connecting the first board and the second board, and
the flexible connecting substrate includes wirings extending between the first board and the second board.

5. The semiconductor storage device according to claim 4, wherein
the flexible conductive part is a flexible substrate.

6. The semiconductor storage device according to claim 1, wherein
the connector is a connector complied with USB standard.

7. The semiconductor storage device according to claim 1, wherein
the first board and the semiconductor memory component form a board-mounted body,
the board-mounted body has an upper surface and a lower surface in a thickness direction of the first board, and
in the thickness direction, the flexible conductive part is disposed at a position lower than or equal to the upper surface and at a position higher than or equal to the lower surface.

8. The semiconductor storage device according to claim 1, wherein
the casing includes a first casing member, a second casing member, and a welded portion connecting the first casing member to the second casing member, and
the first casing member and the second casing member are disposed at both sides in thickness directions of the first board and the second board so as to cover the first board and the second board.

9. The semiconductor storage device according to claim 1, wherein
the casing includes a first casing member, a second casing member, and an engaged portion connecting the first casing member to the second casing member, and
the first casing member and the second casing member are disposed at both sides in thickness directions of the first board and the second board so as to cover the first board and the second board.
